(19) United States
(12) Patent Application Publication
(10) Pub. No.: US 2011/0042576 A1
(43) Pub. Date: Feb. 24, 2011

(54) DIRECT WAFER-BONDED THROUGH-HOLE PHOTODIODE

(75) Inventors: Robin WILSON, Holywood (GB); Cormac MACNAMARA, Belfast (GB)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: ICEMOS TECHNOLOGY LTD., Belfast (GB)

(21) Appl. No.: 12/860,024

(22) Filed: Aug. 20, 2010

Related U.S. Application Data
(60) Provisional application No. 61/235,596, filed on Aug. 20, 2009.

(51) Int. Cl. G01T 1/20; H01L 31/105; H01L 31/18

(52) U.S. Cl. 250/370.11; 257/458; 438/73; 257/E31.061

(57) ABSTRACT

A photodetector array comprises a plurality of photodetectors formed by a high resistivity low doping concentration first semiconductor substrate and a low resistivity high doping concentration second semiconductor substrate. The first and second semiconductor substrates are directly bonded together with a silicon-to-silicon atomic bond at a bond interface, thereby providing a sharp transition from the first substrate to the second substrate. A method of making the photodetector array is also provided.

### CROSS-REFERENCE TO RELATED APPLICATIONS

This application claims priority to U.S. Provisional Patent Application No. 61/235,596 filed Aug. 20, 2009.

### BACKGROUND OF THE INVENTION

Photodetector arrays which use arrays of silicon photodiodes are commonly used in medical imaging systems. U.S. Patent Publication No. 2006/0097290 (Hietanen) describes various structures for use in such arrays. However, there is still a need for improved arrays that overcome certain limitations in prior art arrays and which provide improved performance. The present invention fulfills this need.

### BRIEF SUMMARY OF THE INVENTION

A photodetector array comprises a plurality of photodetectors formed by a high resistivity low doping concentration first semiconductor substrate and a low resistivity high doping concentration second semiconductor substrate. The first and second semiconductor substrates are directly bonded together with a silicon-to-silicon atomic bond at a bond interface, thereby providing a sharp transition from the first substrate to the second substrate. A method of making the photodetector array is also provided.

### BRIEF DESCRIPTION OF THE DRAWINGS

The foregoing summary, as well as the following detailed description of preferred embodiments of the invention, will be better understood when read in conjunction with the appended drawings. For the purpose of illustrating the invention, there is shown in the drawings embodiments which are presently preferred. However, the invention is not limited to the precise arrangements and instrumentalities shown.

In the drawings:

FIG. 1 shows a typical PIN (P region/instrinsic region/N region) doping profile using Si—Si material in accordance with preferred embodiments of the present invention.

FIG. 2 shows a via manufacturing flow in accordance with preferred embodiments of the present invention.

FIG. 3 shows a semiconductor device in the form of a photodiode array that includes two wafer substrates bonded together in accordance with preferred embodiments of the present invention.

FIG. 4 shows a bump termination in accordance with preferred embodiments of the present invention.

FIG. 5 shows a radiation detector in accordance with preferred embodiments of the present invention.

FIG. 6 shows an imaging system that comprises an X-ray source (X-ray Tube) and a radiation detector in accordance with preferred embodiments of the present invention.

FIG. 7 shows a method of manufacturing a plurality of photodiodes in accordance with preferred embodiments of the present invention.

FIG. 8 shows parameters of a trumpet etch process in accordance with preferred embodiments of the present invention.

FIGS. 9-11 show alternative embodiments of two wafer substrates bonded together in accordance with preferred embodiments of the present invention.

### DETAILED DESCRIPTION OF THE INVENTION

Certain terminology is used herein for convenience only and is not to be taken as a limitation on the present invention.

A photodetector array is provided that includes a plurality of sub-array photodetectors formed by silicon to silicon (“Si to Si” or “Si—Si”) bonding of two specially prepared silicon substrates, specifically, a silicon substrate with a high doping concentration bonded to a silicon substrate with a low doping concentration. Printed wiring circuitry are provided on the substrates for continuous anode cathode connections on the top side of one substrate (the low doping concentration substrate) and the bottom side of the other substrate (the high doping concentration substrate).

Benefits of such a structure include:

1. Allows for higher resistivity intrinsic regions (intrinsic layers or i-layers) to improve responsivity.

2. Lowers capacitance.

3. Lowers cost of Low Cost.

4. Allows for a front lit photodiode configuration.

5. Provides a Through-Silicon Via (TSV).

6. Allows for printed wiring circuitry on the top side of one substrate (the low doping concentration substrate) for connection between the photodiode anode and the through-hole via (TSV).

7. Allows for printed wiring circuitry on the bottom side of the other substrate (the high doping concentration substrate) for connection between the photodiode cathode and the through-hole via (TSV).

One preferred embodiment of the present invention provides for a front lit tile comprised of a plurality of photodiodes. The photodiodes are formed using two uniquely different substrate concentrations bonded together. A first semiconductor substrate has a first doping concentration that is low. A second semiconductor substrate has a second doping concentration that is high. A Silicon-on-Silicon atomic bond is formed between the first and second substrates to create an almost perfect high concentration/low concentration junction that provides a sharp transition from the high concentration substrate to the low concentration substrate.

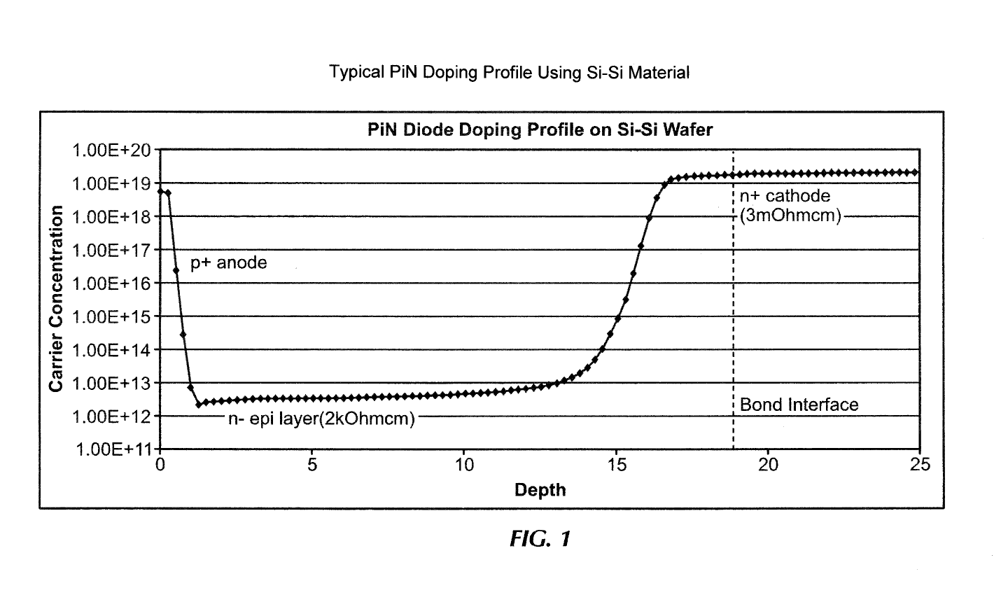

(1) FIG. 1 shows a typical PIN (P region/intrinsic region/N region) doping profile using Si—Si material.

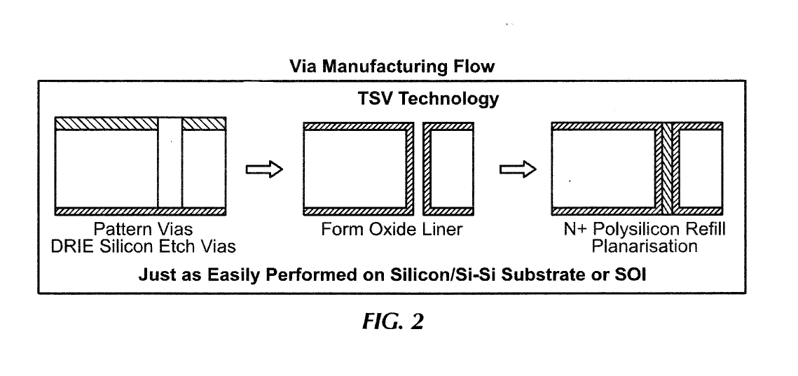

The plurality of photodiodes are provided with adjacent through-hole conductive vias that are electrically isolated from both substrates, illustrated in FIG. 2. (In FIG. 2, “SOI” refers to “silicon on insulator” and “TSV” refers to “through-silicon via.”)

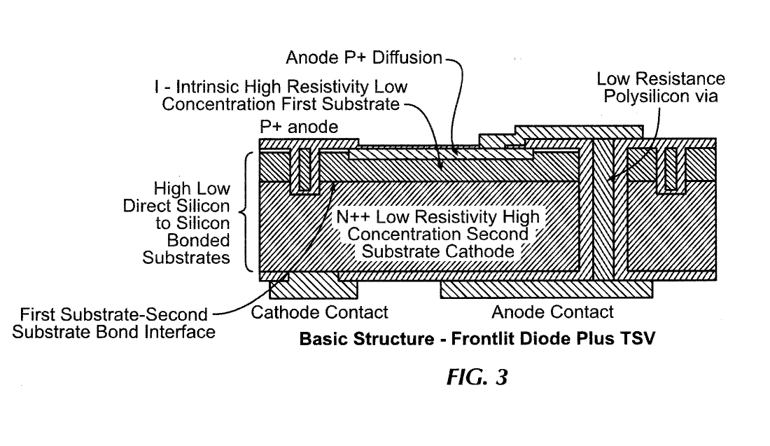

FIG. 3 shows a semiconductor device in the form of a photodiode array that includes two wafer substrates bonded together, labeled as “high low direct silicon to silicon bonded substrates.” In one preferred embodiment, the substrates comprise (1) an intrinsic i-type high resistivity low concentration first substrate, referred to herein as “the first substrate” or “i-layer,” and (2) a n++ low resistivity high concentration (heavily doped) second substrate, referred to herein as “the second substrate.” The second substrate acts as a cathode.

A bonded interface exists between the two substrates, labeled in FIG. 3 as “first substrate-second substrate bond interface.” During high temperature processing, the transition between the low concentration of the first substrate (i-layer) and the high concentration of the second substrate (cathode wafer) will actually move into the first substrate.

A plurality of doped electrically isolated through-silicon vias longitudinally traverse the first and second substrates from the top of the first substrate to the bottom of the second substrate. The vias include continuous anode cathode electrical connections. The vias may be filled with low resistance polysilicon.

A p+ anode is formed in the top of the first substrate and is electrically connected to the via. An anode p+ diffusion is formed into the top of the first substrate. A cathode contact is formed on the bottom (underside or backside) of the second substrate, thereby providing an electrical connection for the cathode (second substrate) at the bottom or base of the wafer device. An anode contact is also formed on the bottom (underside or backside) of the second substrate in electrical contact with the electrical connections of the via, thereby providing an electrical connection for the anode at the bottom or base of the wafer device. Together, the p+ anode, the i-layer (first substrate) and the n++ second substrate forms a PIN configuration.

The i-layer separates the anode from the cathode contact region of the second substrate. The i-layer therefore separates the plurality of photodiodes on the first substrate front surface of the semiconductor device from the cathode contact region of the second substrate. The i-layer is the region into which the depletion region (when the anode is biased with respect to the cathode) spreads. It is the region where the electron hole pairs are formed due to incoming radiation. These pairs are the quanta of the current which ultimately flows between anode and cathode when light is shined on the device.

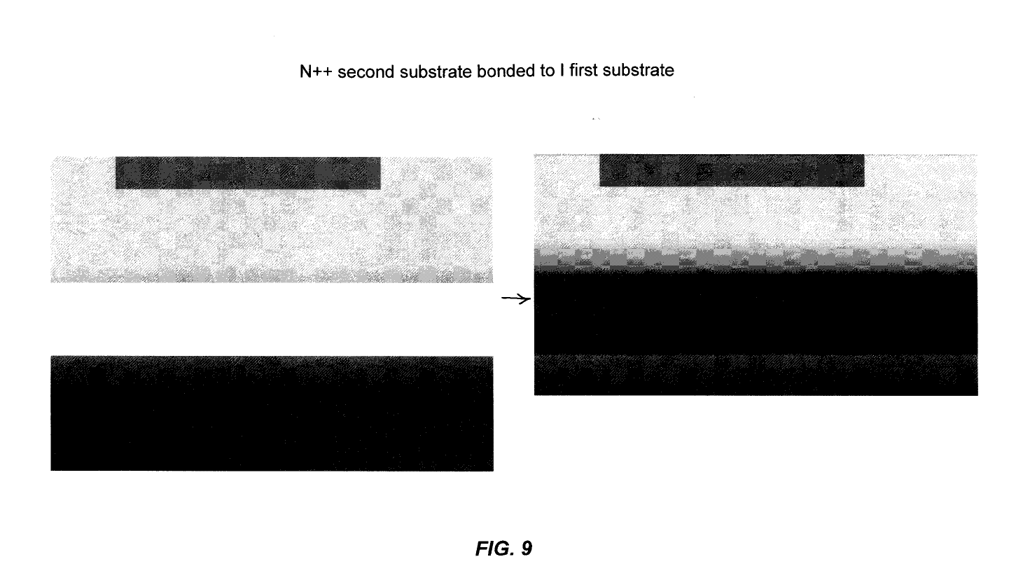

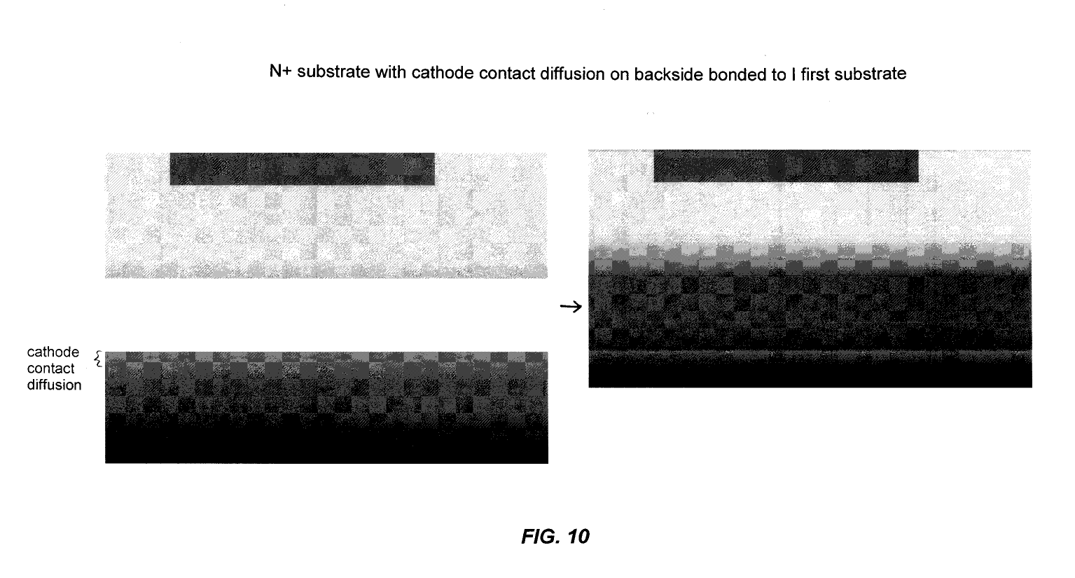

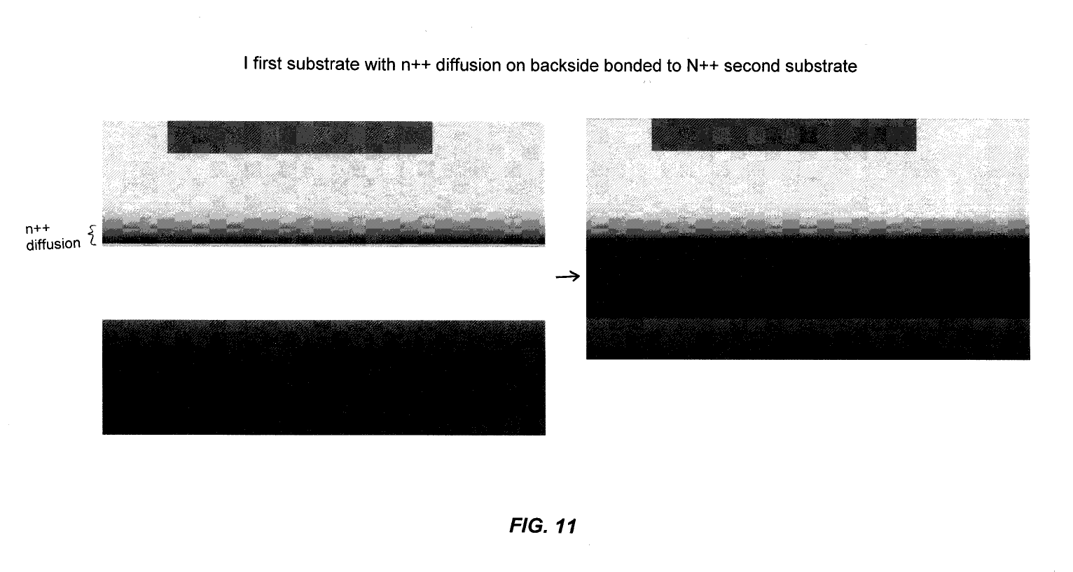

FIGS. 9-11 show alternative embodiments of the two wafer substrates bonded together that are within the scope of the present invention. In FIG. 3, the first substrate is an i-layer with a p+ anode formed in the top of it, and the second substrate is n++, as shown in simplified form in FIG. 9. In FIG. 10, the second substrate is a n+substrate with cathode contact diffusion on its backside bonded to the first substrate which is an i-layer with a p+ anode formed in the top of it. In FIG. 11, the first substrate additionally includes an n++ diffusion on its backside bonded to a n++ second substrate.

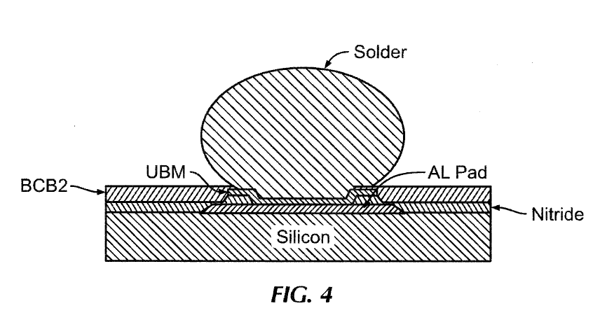

Anode and Cathode termination connection to System comprises an array of Chip Scale Solder bumps and double-sided electrodes. The bump termination is shown in FIG. 4. The electrical connection electrodes for the photodiodes has electrodes on the surface of the first substrate connected to the top of the through hole via on the first substrate surface and a further separate electrode on the surface of the opposite side of the second substrate connected to the bottom of the through hole via.

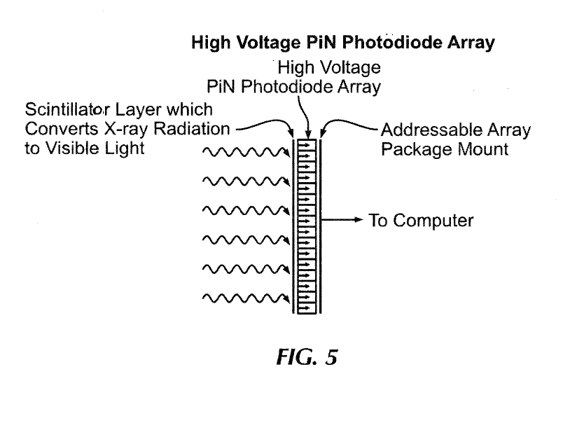

FIG. 5 shows a radiation detector that comprises a scintillator layer which converts X-ray radiation to visible light, a PIN Photodiode array, and addressable array package mounting.

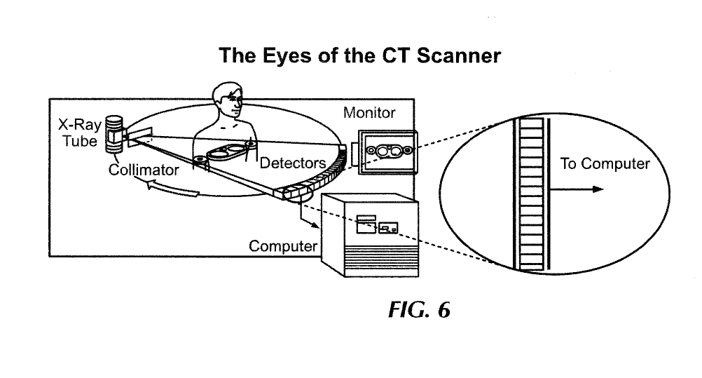

FIG. 6 shows an imaging system that comprises an X-ray source (X-ray Tube) and a radiation detector. The X-ray source faces the radiation detector and a computer controls the source and detector to process electrical signals from the radiation detector.

The radiation detector includes at least one front lit photodiode. In one preferred embodiment, the photodiode has the configuration shown in FIG. 3 and described above. Anode and Cathode termination connection to the system comprises an array of Chip Scale Solder bumps which are also described above.

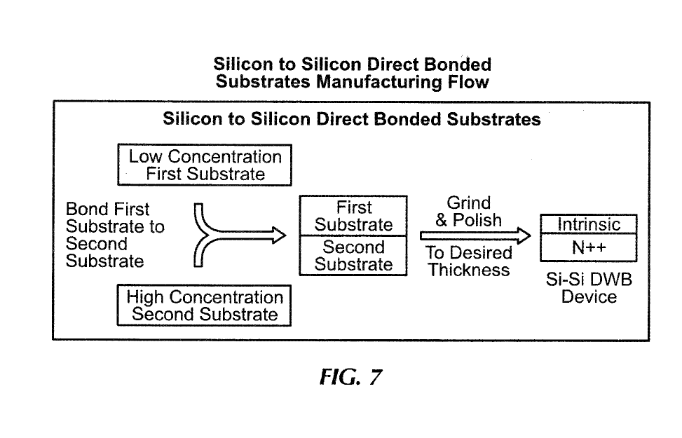

A method of manufacturing the plurality of photodiodes comprises the following steps (see, also FIG. 7):

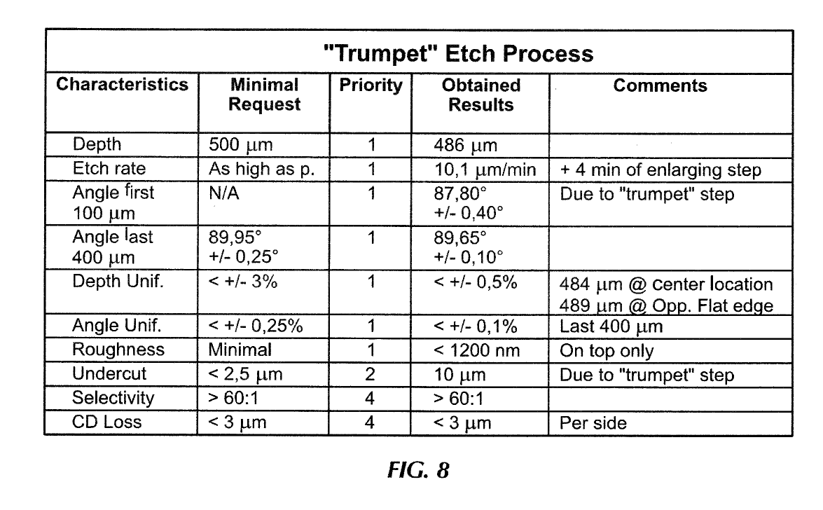

1. First Substrate Preparation. As a starting base for the Si to Si substrate, an ultra-flat wafer with low doping concentration is required. This wafer is developed by mechanically grinding a commercially supplied silicon wafer in a precision grinding machine. The grinding technology is fully automated and the process capability is such that the total thickness variation (TTV) on a 100 mm-200 mm silicon wafer can be reduced to <0.3 um, while also controlling the shape of that wafer so that each not only has a very low TTV but also has a repeatable shape. The absolute thickness of this substrate is also controlled very tightly to less than +/−0.5 um. Current processes are limited in absolute thickness only by the ability to reliably handle the wafers post-grind down to 300 um on a 150 mm wafer.
2. Second Substrate. After selecting a High Concentration substrate wafer and grinding this substrate wafer to its desired thickness, the second subwafer is polished to provide a high quality surface that can be readily bonded to the device wafer. Careful parameter control is provided to the automated precision polishers to retain the wafer shape. Increases in TTV caused by polishing causes are minimized by removing only the amount of silicon necessary to repair any damage to the underlying silicon crystal caused by the grinding process. Current capabilities allow for control of TTV post-handle polish on 100 mm-150 mm wafers to <0.6 um while maintaining a constant wafer shape. The quality of the polished front surface compares very favorably with the standard provided by commercial silicon wafer providers. Average roughness is typically around 3 A-4 A (measured on a 25 um×25 um sample). The absolute thickness of the wafer is tightly controlled, with wafers coming from handle polish varying in absolute thickness by less than +/−0.5 um.
3. Wafer Bonding. The first substrate and second substrate are brought together (FIG. 7) under very controlled conditions to ensure the elimination of all particles on either wafer prior to contacting. The environment in which this is done is locally filtered to better than class I (ISO 14644 standard). The tooling is fully automated and can offer wafer bonding in either air, vacuum or an inert atmosphere, depending on what is required. The equipment has integrated cleaning which can be used to provide a hydrophilic or hydrophobic surface on device and handle wafers prior to joining, again depending on the application and process. Full strength wafer bonding is completed by heating the bonded wafer pair in a furnace at greater than 1050 degrees Celsius (C).
4. Deep Silicon Etch. Deep reactive ion etching (DRIE) ICP anisotropic etch tools with etch rate capability of 5 um/min for high aspect ratio silicon etch uses the trumpet etch process. See FIG. 8.

Ta oxide/poly refill is employed using any combination of dry thermal or low-pressure CVD TEOS-deposited oxides and low temperature CVD polysilicon processes (the CVD processes are furnace-based batch processes). Typical configurations are TEOS liner followed by polysilicon bulk refill. Within this scheme, TEOS liner processes depositing sidewall thicknesses from 0.2 um up to 1.0 um are available with top surface conformalties between 70% and 100%. The standard polysilicon deposition process used is a 2 um deposition process. In order to refill trenches as wide as 10 um, repeat depositions are made until complete refill is achieved. Process Control on the TEOS and polysilicon deposition is better than +/−10C %.

5. Planarization. In the course of trench refill, polysilicon deposits form on the surface of the bonded wafer. A polish planarization process is used that preferentially removes polysilicon rather than oxide by exploiting differences in the relative hardness of the two materials. The process in essence removes the overlying polysilicon, stopping on the TEOS oxide to leave a planar wafer surface for future processing.
6. Anode/Cathode formation: This continuous anode cathode connection includes at least one electrode circuit and one electrically isolated through hole via in the Si to Si Bonded Device selectively masking the first substrate with a first mask and doping the first substrate to form the anode on the intrinsic region side. The second substrate also has at least one electrode circuit on the bottom surface with both Anode and Cathode Terminations on the bottom side of the second substrate. These anode cathode terminations and electrode circuitry are formed by selectively masking the second substrate with a second mask post the bonding of the first substrate intrinsic layer to the second n++ substrate and the deployment of double sided alignment techniques.

Another preferred embodiment of the present invention provides a radiation detector using an X-ray sensitive scintillator layer which converts X-ray radiation to visible light, and then a photodiode array converts the visible light to an electrical signal for an addressable signal to a CMOS Integrated Sensor Circuit. This radiation detector includes at least one front lit photodiode. In one preferred embodiment, the photodiode has the configuration shown in FIG. 3 and described above. Anode and Cathode termination connection to the system comprises an array of Chip Scale Solder bumps which are also described above.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention.

What is claimed is:

1. A photodetector array comprising a plurality of photodetectors formed of:
(a) a high resistivity low doping concentration first semiconductor substrate; and
(b) a low resistivity high doping concentration second semiconductor substrate, wherein the first and second semiconductor substrates are directly bonded together with a silicon-to-silicon atomic bond at a bond interface, thereby providing a sharp transition from the first substrate to the second substrate.

2. The photodetector array of claim 1 further comprising:
a p+ anode formed in the top surface of the first substrate;
an anode contact formed on the bottom surface of the second substrate; and
a plurality of electrically isolated through silicon vias that longitudinally traverse the first and second substrates from the top surface of the first substrate to the bottom surface of the second substrate, the top of each via being in electrical contact with the p+ anode and the bottom of the via being in electrical contact with the anode contact.

3. The photodetector array of claim 2 wherein the vias are filled with low resistance polysilicon.

4. The photodetector array of claim 1 wherein the first substrate is an intrinsic i-type high resistivity low doping concentration silicon substrate, and the second substrate is a n++ low resistivity high doping concentration silicon substrate, the photodetector array further comprising:
a p+ anode formed in the top surface of the first substrate,
wherein the p+ anode, the first substrate and the second substrate forms a P region/intrinsic region/N region (PIN) configuration.

5. The photodetector array of claim 1 wherein the first substrate is an intrinsic i-type high resistivity low doping concentration silicon substrate, and the second substrate is a n+ low resistivity high doping concentration silicon substrate, the photodetector array further comprising:
a p+ anode formed in the top surface of the first substrate, and
a cathode contact diffusion on the backside of the second substrate.

6. The photodetector array of claim 1 wherein the first substrate is an intrinsic i-type high resistivity low doping concentration silicon substrate, and the second substrate is a n++ low resistivity high doping concentration silicon substrate, the photodetector array further comprising:
a p+ anode formed in the top surface of the first substrate,
a n++ diffusion on the backside of the first substrate.

7. The photodetector array of claim 1 wherein the second substrate acts as a cathode, the photodetector array further comprising:
a cathode contact formed on the bottom surface of the second substrate, thereby providing an electrical connection for the second substrate at the bottom of the plurality of photodetectors.

8. The photodetector of claim 1 wherein the plurality of photodetectors define a front lit tile.

9. A radiation detector comprising:
(a) a scintillator layer that converts X-ray radiation to visible light; and
(b) a photodiode array that converts the visible light to an electrical signal, the photodiode array including a plurality of photodetectors formed of:
(i) a high resistivity low doping concentration first semiconductor substrate; and
(ii) a low resistivity high doping concentration second semiconductor substrate, wherein the first and second semiconductor substrates are directly bonded together with a silicon-to-silicon atomic bond at a bond interface, thereby providing a sharp transition from the first substrate to the second substrate.

10. The radiation detector of claim 9 wherein the plurality of photodetectors define a front lit tile.

11. An X-ray CT scanner comprising:
(a) a scintillator layer that converts X-ray radiation to visible light; and
(b) a photodiode array that converts the visible light to an electrical signal, the photodiode array including a plurality of photodetectors formed of:
(i) a high resistivity low doping concentration first semiconductor substrate; and
(ii) a low resistivity high doping concentration second semiconductor substrate, wherein the first and second semiconductor substrates are directly bonded together with a silicon-to-silicon atomic bond at a bond interface, thereby providing a sharp transition from the first substrate to the second substrate.

12. The X-ray CT scanner of claim 11 wherein the plurality of photodetectors define a front lit tile.

13. A method of making a plurality of photodetectors comprises:
(a) providing a high resistivity low doping concentration first semiconductor substrate;
(b) providing a low resistivity high doping concentration second semiconductor substrate; and
(c) bonding the first and second substrates together to form a single structure, wherein a silicon-to-silicon atomic bond is formed at a bond interface, thereby providing a sharp transition from the first substrate to the second substrate.

14. The method of claim 13 wherein the first substrate is an intrinsic i-type high resistivity low doping concentration silicon substrate, and the second substrate is a n++ low resistivity high doping concentration silicon substrate.

15. The method of claim 13 further comprising:
(d) heating the bonded single structure to greater than 1050 degrees Celsius.

16. A photodetector array comprising a plurality of photodetectors having double-sided electrodes, the plurality of photodetectors comprising:
(a) a semiconductor substrate having a top and bottom surface;
(b) a first electrode on the top surface of the substrate;
(c) a second electrode on the bottom surface of the substrate;
(d) a plurality of electrically isolated through silicon vias that longitudinally traverse the substrate from the top surface of the substrate to the bottom surface of the substrate, the vias including continuous electrical connections therethrough, wherein the top of each via is electrically connected to the first electrode, and the bottom of each via is electrically connected to the second electrode, thereby providing the plurality of photodetectors with double-sided electrodes.

17. The photodetector array of claim 16 wherein the first electrode is a p+ anode and the second electrode is an anode contact.

18. The photodetector array of claim 16 wherein the vias are filled with low resistance polysilicon which is used to make the continuous electrical connections through the vias.

19. The photodetector array of claim 16 wherein the semiconductor substrate is formed of:
(i) a high resistivity low doping concentration first semiconductor substrate, and
(ii) a low resistivity high doping concentration second semiconductor substrate, wherein the first and second semiconductor substrates are directly bonded together with a silicon-to-silicon atomic bond at a bond interface, thereby providing a sharp transition from the first substrate to the second substrate.
